(19) United States
(12) Patent Application Publication
(10) Pub. No.: US 2007/0169919 A1
(43) Pub. Date: Jul. 26, 2007

(54) HEAT PIPE TYPE HEAT DISSIPATION DEVICE

(75) Inventors: GEN-PING DENG, SHENZHEN (CN); YI-QIANG WU, SHENZHEN (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: FOXCONN TECHNOLOGY CO., LTD., TU CHENG (TW)

(21) Appl. No.: 11/308,852

(22) Filed: May 15, 2006

(30) Foreign Application Priority Data
Jan. 21, 2006 (CN) 200610033242.6

(51) Int. Cl. H05K 7/20

(52) U.S. Cl. 165/104.33; 361/700; 257/715

(57) ABSTRACT

A heat pipe type heat dissipation device for an electronic component comprises a base, a bended heat pipe with an evaporating portion connected to the base and at least one condensing portion extending from the evaporating portion, and at least two heat sinks thermally combined together and sandwiching the condensing portion of the heat pipe therebetween. A turning angle of more than 90 degrees and less than 180 degrees, preferably ranging from 120 degrees to 150 degrees, is defined between the evaporating portion and the condensing portion of the heat pipe. The heat sinks each have a heat spreader and a plurality of fins extending from a lateral face of the heat spreader. The condensing portion of the heat pipe is sandwiched between the heat spreaders of the heat sinks.

### FIELD OF THE INVENTION

The present invention generally relates to heat dissipation devices, and more particularly to a heat pipe type heat dissipation device for removing heat from a heat-generating electronic component.

### DESCRIPTION OF RELATED ART

Computer electronic components, such as central processing units (CPUs), generate great amounts of heat during normal operation. If not quickly removed this can deteriorate their operational stability and damage associated electronic equipment. Thus the heat must be removed quickly to ensure normal operation thereof. A heat sink is often attached to a top surface of a CPU to remove heat therefrom.

A conventional heat sink is made of highly heat-conductive metal, such as copper or aluminum, and generally includes a base portion for contacting the electronic component to absorb heat therefrom and a plurality of fins formed on the base portion for dissipating heat. However, as the operating speed of electronic components has been continually upgraded, these kinds of conventional heat sinks can no longer meet the heat dissipation requirements of modern IC packages. In recent years, heat pipes have been widely used due to their great heat-transferring capability. Accordingly, heat sinks equipped with heat pipes are devised in various manners.

A typical heat sink with heat pipes is illustrated in FIG. 6. The heat sink has a base 100, two vertical U-shaped heat pipes 200 (only one shown) installed on the base 100 and a plurality of parallel fins 300 through which the heat pipes 200 extend. The heat sink absorbs heat generated by an IC package (not shown) through the base 100. The heat is then speedily transferred, via the heat pipes 200, to the fins 300 for further heat dissipation.

However, this design for a heat sink has a disadvantage in its structure. To ensure manufacturing efficiency, the fins 300 are generally processed with a uniform dimension and hole position, the heat pipe 200 needs to have a straight evaporating portion 220 for engaging with the base 100 and two parallel condensing portions 240 for the uniform-dimensioned fins. The evaporating portion 220 and the condensing portion 240 are generally perpendicular to each other and a perpendicular bend therebetween is formed, that is, there is a turning angle of ninety degrees from the evaporative portion 220 to the condensing portions 240. The right-angled bending decreases the performance of the heat pipe 200. Heat transfer between the portions decreases at the bend, so the heat absorbed by the evaporating portion 220 cannot be quickly transferred to the condensing portions 240. Heat dissipation performance of the whole heat sink is therefore unsatisfactory.

What is needed is a heat pipe type heat sink with an enhanced heat dissipation performance.

### SUMMARY OF THE INVENTION

A heat pipe type heat dissipation device in accordance with a preferred embodiment of the present invention comprises a base, at least one heat pipe having an evaporating portion connected to the base and at least one condensing portion bent from one end of the evaporating portion, and at least two heat sinks thermally combined together and tightly sandwiching the condensing portion of the heat pipe. An angle between the evaporating portion and the condensing portion of the heat pipe is more than 90 degrees and less than 180 degrees.

Many aspects of the present apparatus and method can be better understood with reference to the following drawings. The components in the drawings are not necessarily drawn to scale, the emphasis instead being placed upon clearly illustrating the principles of the present apparatus and method. Moreover, in the drawings, like reference numerals designate corresponding parts throughout the several views. Other advantages and novel features will become more apparent from the following detailed description of preferred embodiment when taken in conjunction with the accompanying drawings, in which:

### BRIEF DESCRIPTION OF THE DRAWINGS

FIG. 1 is an exploded isometric view of a heat pipe type heat dissipation device in accordance with a first embodiment of the present invention;

FIG. 2 is an assembled view of FIG. 1;

FIG. 3 is an exploded isometric view of a heat pipe type heat dissipation device in accordance with a second embodiment of the present invention;

FIG. 4 is an assembled view of FIG. 3;

FIG. 5 is an exploded isometric view of a heat pipe type heat dissipation device in accordance with a third embodiment of the present invention; and

FIG. 6 is a side elevation view of a known heat pipe type heat dissipation device.

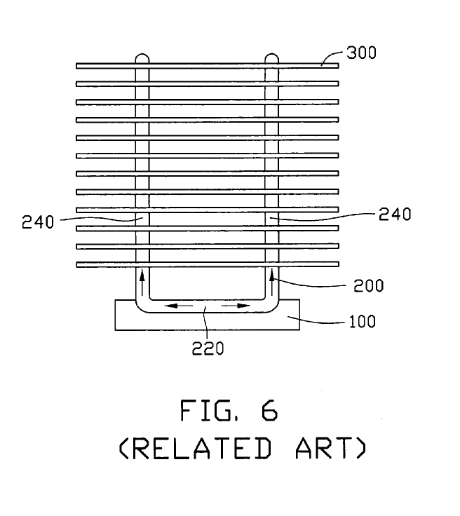

### DETAILED DESCRIPTION OF THE INVENTION

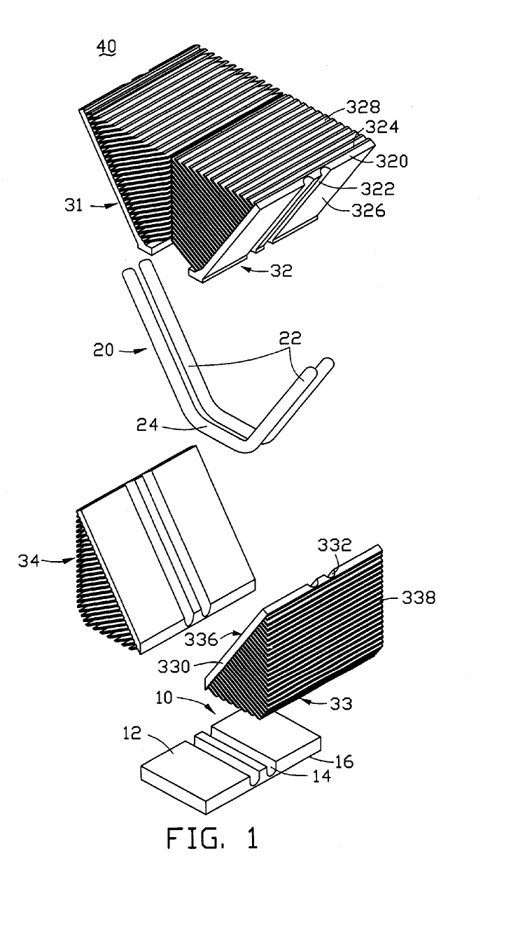

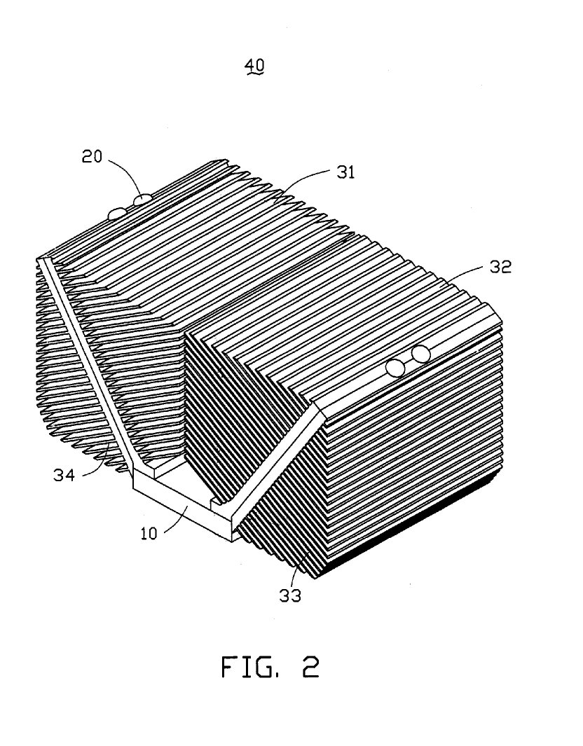

Referring to FIGS. 1 and 2, a heat pipe type heat dissipation device 40 in accordance with a preferred embodiment of the present invention is used to dissipate heat from an electronic component (not shown). The heat dissipation device 40 has a wholly cuboid configuration and comprises a base 10, two pairs of heat sinks 31, 32, 33, 34 and two heat pipes 20 connecting the heat sinks 31-34 with the base 10.

The base 10 is a rectangular flat plate having a bottom face 16 for contacting the electronic component to absorb heat therefrom and a top face 12 opposite to the bottom face 16 and defining two parallel grooves 14 thereon.

One pair of the heat sinks 31-34 is named first heat sink 31, 32, and the other pair is named second heat sink 33, 34. The first and second heat sinks 31, 32, and 31,34 have a similar structure, which are selectively described by illustrating the first heat sink 32 and the second heat sink 33 as follows. The first heat sink 32 has a triangular prism configuration and comprises a flat plate-shaped heat spreader 320 with two grooves 322 defined on a lateral face 326 thereof, and a plurality of parallel fins 328 extending perpendicularly from an opposite face 324 of the heat spreader 320. The fins 328 decrease in height from the middle to the outboard of the first heat sink 32, and the tips of the fins 328 form a ridge-shaped top portion with a peak (shown but not labeled). The second heat sink 33 comprises a heat spreader 330 with grooves 332 and fins 338, which are constructed in the same manner as the first heat sink 32.

The first heat sink 32 and the second heat sink 33 cooperate with each other. Two adjacent lateral faces 326, 336 having grooves 322, 332 of the first heat sink 32 and the second heat sink 33 contact tightly so that corresponding grooves 322, 332 jointly form two parallel channels (not labeled). The fins 328 of the first heat sink 32 and the fins 338 of the second heat sink 33 are parallel to each other and extend away from each other in opposing directions. Another first heat sink 31 and second heat sink 34 are combined in the same manner as heat sinks 32 and 33. The heat sinks 31-34 are located above the base 10, and the spreaders 320, 330 and those of the heat sinks 31, 34 are positioned at an oblique angle to the base 10.

The heat pipes 20 are connected to the base 10, parallel to each other. Each heat pipe 20 is in a plane perpendicular to the top face 12 of the base 10. The heat pipe 20 has an evaporating portion 24 received in a corresponding groove 14 of the base 10 and two condensing portions 22 extending from opposite ends of the evaporating portion 24 into said channels formed by each pair of heat sinks 31 and 34, 32 and 33, as shown in FIG. 2. The evaporating portion 24 and the condensing portions 22 of the heat pipe 20 are straight. However, a turning angle is defined between the evaporating portion 24 and each of the condensing portions 22. The angle is more than 90 degrees and less than 180 degrees, and preferably ranges from 120 degrees to 150 degrees. The first heat sinks 31, 32 are located at the inner side of the turning angle of each heat pipe 20, and the second heat sinks 33, 34 on the outside. That is, two first heat sinks 31, 32 are situated between the condensing portions 22 of each heat pipe 20; the heat pipes 20 extend between the second heat sinks 33, 34. The condensing portions 22 of each heat pipe 20 are respectively sandwiched between the first heat sink 31 and second heat sink 34 and the first heat sink 32 and second heat sink 33. The heat sinks 31-34 and the heat pipes 20, the heat pipes 20 and the base 10 are connected together by soldering.

When the heat dissipation device 40 is applied to the heat-producing electronic component, the base 10 absorbs heat from the electronic component and conducts it to the evaporating portions 24 of the heat pipes 20. The heat then travels fluently along the heat pipe 20, from the evaporating portions 24 to the condensing portions 22 and further to the heat sinks 31-34. The heat sinks 31-34 dissipate the heat via their fins, selectively labeled by 328, 338 as above. Due to the obtuse angle between the evaporating portion 24 to the condensing portion 22 of each heat pipe 20 in comparison to the right angle in prior art, the heat can be more easily transferred between the evaporating portion 24 and condensing portion 22 of the heat pipe 20; accordingly, efficiency of the heat pipe 20 in the heat dissipation device 40 is improved, further enhancing heat dissipation performance of the whole heat dissipation device. Connection of the heat pipes 20 and the heat sinks 31-34 can be easily accomplished by the first heat sinks 31, 32 and the second heat sinks 33, 34 sandwiching the heat pipes 20 when being combined, and an excellent thermal contact between the heat pipes 20 and the heat sinks 31-34 can thus be achieved.

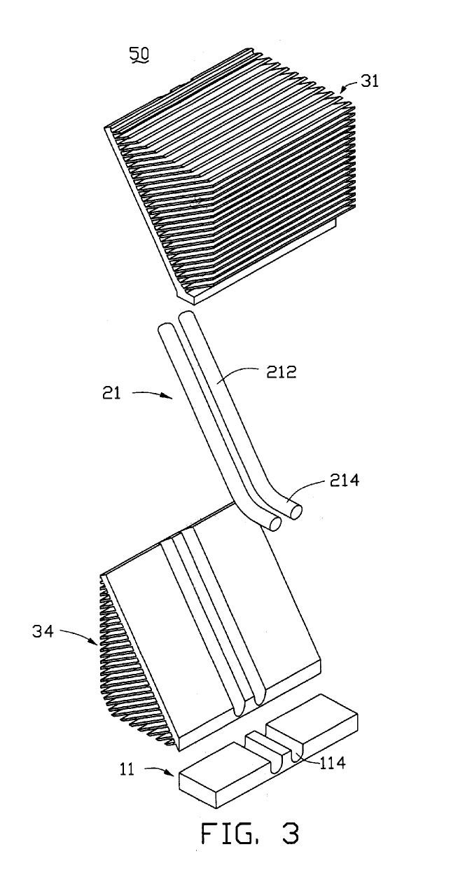

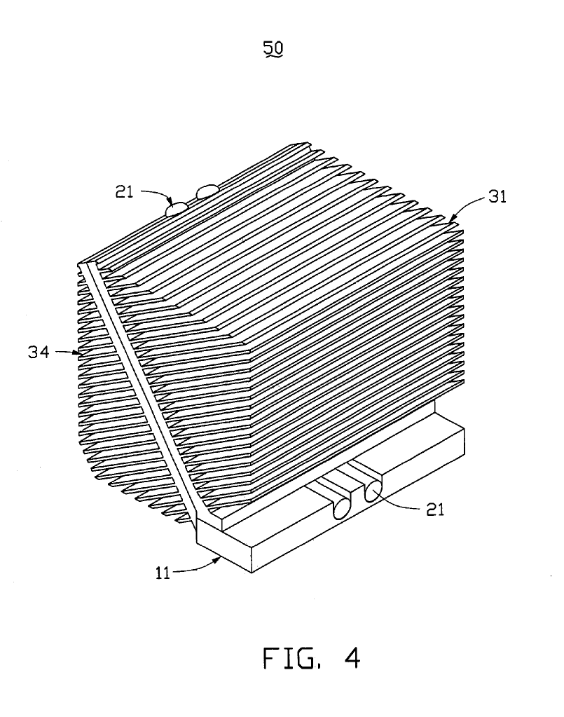

A heat dissipation device 50 in accordance with a second embodiment of the present invention is illustrated in FIGS. 3 and 4. It can be seen that the heat dissipation device is a half of that of the first embodiment. The heat dissipation device 50 comprises a base 11, two heat sinks 31, 34 and two heat pipes 21 attaching the heat sinks 31, 34 to the base 11. The heat pipe 21 has only one evaporating portion 214 and one condensing portion 212 bent from one end of the evaporating portion 214. A turning angle, which is more than 90 degrees and less than 180 degrees, is defined between the two parts 212, 214 of the heat pipe 21. The evaporating portion 214 of the heat pipe 21 is received in a groove 114 defined in the base 11 and the condensing portion 212 is sandwiched between the heat sinks 31, 34, which are combined together by the same manner as the first embodiment.

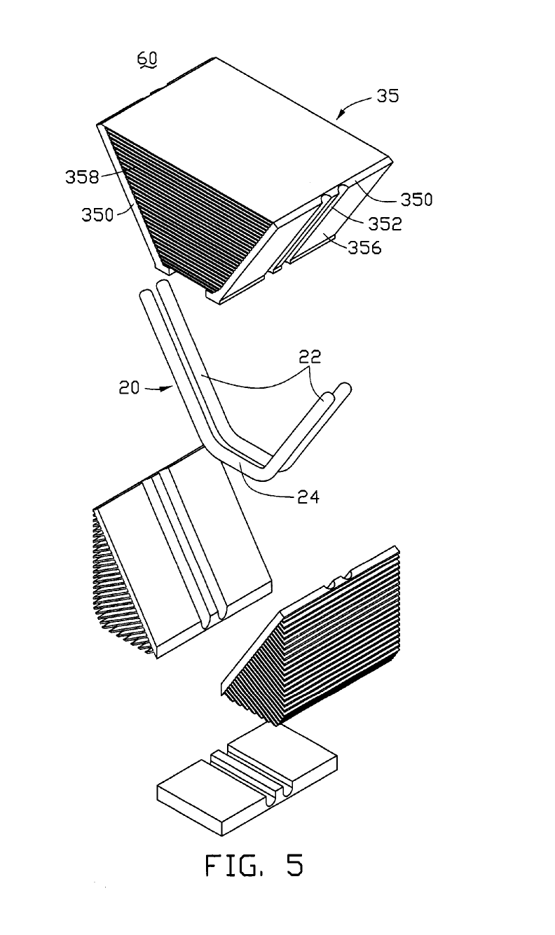

A heat dissipation device 60 in accordance with a third embodiment of the present invention is illustrated in FIG. 5. The heat dissipation device 60 has a similar structure to that of the first embodiment, but a unitary heat sink 35 instead of the two first heat sinks 31, 32 of the first embodiment. The unitary heat sink 35 is situated between the condensing portions 22 of each heat pipe 20. The heat sink 35 comprises two oblique heat spreaders 350 and a plurality of parallel fins 358 connecting the heat spreaders 350. Two grooves 352 are defined on an outer lateral face 356 of each of the heat spreaders 350. Other structure and connection manner between all the elements are same as the first embodiment.

In above described embodiments of the present invention, the heat pipes 20, 21 are bent in such a manner that a turning angle more than 90 degrees and less than 180 degrees is defined in the transition between adjacent evaporating portion 22, 214 and condensing portion 24, 212. The obtuse angle transition can decrease the negative effect resulting from the right-angled bend of the heat pipes of the conventional art so as to improve the utility of heat pipes 20, 21, further to enhance heat dissipation performance of the whole heat dissipation device 40, 50, 60.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat pipe type heat dissipation device comprising:
a heat pipe with an evaporating portion connected to the base and at least one condensing portion extending from one end of the evaporating portion, with an turning angle more than 90 degrees and less than 180 degrees defined between the evaporating portion and the at least one condensing portion; and
at least two heat sinks thermally combined together and sandwiching the at least one condensing portion of the heat pipe therebetween.

2. The heat dissipation device as described as claim 1, wherein the at least two heat sinks each comprise a flat heat spreader and a plurality of fins extending from a surface of the heat spreader, and the at least one condensing portion of the heat pipe is sandwiched between the heat spreaders.

3. The heat dissipation device as described as claim 2, wherein the at least two heat sinks each have a prism-shaped configuration in which the fins decreasing in height from a middle to an outboard of the heat spreader are arranged.

4. The heat dissipation device as described as claim 1, wherein at least one groove is defined in the base for receiving the evaporating portion of the heat pipe.

5. The heat dissipation device described as claim 2, wherein the heat spreaders of the at least two heat sinks define grooves for receiving the at least one condensing portion of the heat pipe in a surface opposite to that provided with the fins.

6. The heat dissipation device as described as claim 3, wherein the fins of the at least two heat sinks are parallel to each other.

7. The heat dissipation device as described as claim 6, wherein the fins of the at least two heat sinks extend in opposing directions.

8. The heat dissipation device as described as claim 1, the at least two heat sinks together form a cuboid configuration.

9. The heat dissipation device as described as claim 1, wherein the angle between the evaporative portion and the at least one condensing portion ranges from 120 degree to 150 degree.

10. The heat dissipation device as described as claim 9, wherein the evaporating portion and the at least one condensing portion both are straight.

11. The heat dissipation device as described as claim 2, wherein the heat spreaders are oblique to the base.

12. The heat dissipation device as described as claim 1, wherein the heat pipe is in a plane perpendicular to the top face of the base, including one evaporating portion and two condensing portions bent from opposite ends of the evaporating portion.

13. The heat dissipation device as described as claim 12, wherein the at least two heat sinks comprise two pairs of heat sinks, the two pairs of heat sinks sandwich the two condensing portions of the heat pipe, respectively.

14. The heat dissipation device as described as claim 13, wherein two of the heat sinks are situated between the condensing portions of the heat pipe, and the others are positioned outside.

15. The heat dissipation device as described as claim 14, wherein the heat sinks each include a heat spreader and a plurality of fins extending from the heat spreader, the heat spreaders of the heat sinks between the condensing portions of the heat pipe are at an oblique angle to each other, and the heat spreaders of the other two are also at an oblique angle to each other.

16. The heat dissipation device as described as claim 12, wherein the at least two heat sinks comprises three heat sinks, and one of them is situated between the condensing portions of the heat pipe, the others combined with said one and sandwich jointly respective condensing portions of the heat pipe.

17. The heat dissipation device as described as claim 16, wherein the heat sink between the condensing portions of the heat pipe includes two oblique heat spreaders and a plurality of parallel fins connecting the heat spreaders.

18. A heat dissipation device comprising:
a base having a bottom face for thermally contacting with a heat-generating electronic component;
a heat pipe having an evaporating portion thermally connecting with the base and a condensing portion extending from the evaporating portion with an angle larger than 90 degrees and smaller than 180 degrees in relative to the evaporating portion; and
two heat sinks sandwiching the condensing portion therebetween and thermally connecting therewith, the two heat sinks having fins extending therefrom along different directions.

19. The heat dissipation device as described in claim 18, wherein the different directions are opposite to each other.

20. The heat dissipation device as described in claim 19, wherein the angle is between 120 and 150 degrees.
